(19) United States
(12) Patent Application Publication
(10) Pub. No.: US 2017/0148948 A1
(43) Pub. Date: May 25, 2017

(54) Nitride Light Emitting Diode

(71) Applicant: XIAMEN SANAN OPTOELECTRONICS TECHNOLOGY CO., LTD., Xiamen (CN)

(72) Inventors: Jinjian ZHENG, Xiamen (CN); Feilin XUN, Xiamen (CN); Zhiming LI, Xiamen (CN); Heqing DENG, Xiamen (CN); Weihua DU, Xiamen (CN); Chen-ke HSU, Xiamen (CN); Mingyue WU, Xiamen (CN); Chilun CHOU, Xiamen (CN); Feng LIN, Xiamen (CN); Shuiqing LI, Xiamen (CN); Junyong KANG, Xiamen (CN)

(73) Assignee: XIAMEN SANAN OPTOELECTRONICS TECHNOLOGY CO., LTD., Xiamen (CN)

(21) Appl. No.: 15/424,765

(22) Filed: Feb. 3, 2017

Related U.S. Application Data
(63) Continuation of application No. PCT/CN2015/097563, filed on Dec. 16, 2015.

(30) Foreign Application Priority Data
Jan. 12, 2015 (CN) 201510013715.5

(51) Int. Cl. H01L 33/06; H01L 33/14; H01L 33/12; H01L 33/32

(52) U.S. Cl. CPC H01L 33/06; H01L 33/325; H01L 33/145; H01L 33/12

(57) ABSTRACT

A nitride light emitting diode includes: an n-type nitride layer, a light emitting layer and a p-type nitride layer in sequence, wherein, the light emitting layer is a MQW structure composed of a barrier layer and a well layer, in which, an AlGaN electron tunneling layer is inserted into at least one well layer closing to the n-type nitride layer with barrier height greater than that of the barrier layer; in addition, the barriers of the AlGaN electron tunneling layer and the well layer are high enough so that electrons are difficult to transit towards thermionic emission direction, but mainly transit through tunneling in the InGaN well layers, which confines electron mobility and adjusts electron distribution. Hence, electrons have less chance to spill over into the P-type nitride layer.

### CROSS-REFERENCE TO RELATED APPLICATIONS

The present application is a continuation of, and claims priority to, PCT/CN2015/097563 filed on Dec. 16, 2015, which claims priority to Chinese Patent Application No. 201510013715.5 filed on Jan. 12, 2015. The disclosures of these applications are hereby incorporated by reference in their entirety.

### BACKGROUND

Compared with conventional light sources, GaN-based light emitting diodes, thanks to long service life, high extraction efficiency, low energy consumption and small size, are widely applied in daily life and tend to be important products in modern lighting development.

In conventional GaN-based LED, the light emitting layer typically has an InGaN/GaN multiple quantum well (MQW). On the one hand, electrons have greater mobility than that of holes and the free electrons have higher concentration than that of free holes, which likely cause non-uniform distribution of electrons and holes in the MQW. Electrons concentrate in MQW layers closing to the n-type layer. Holes concentrate in MQW layers closing to the p-type layer and gradually attenuate towards the n-type direction, which are unfavorable for electron-hole combination; on the other hand, electrons with high concentrations and mobility are prone to spill over into the p-type layers and combine with the ionized holes in the p-type layer, thus leading to low ionization of holes, non-radiative combination, low injection efficiency of holes and efficiency droop effect.

Referring to FIG. 1, at present, an AlGaN electron blocking layer (EBL) with high Al composition (typically, 0.2-0.5) is commonly used to suppress the spill-over of electrons. Although high Al composition confines spill-over of partial electrons into the P-type layer, the increase in Al composition in the AlGaN will rapidly increase Mg ionization and degrade crystal quality significantly. As a result, hole ionization efficiency and concentration decrease sharply, which leads to poor luminance and efficiency; in addition, when high current is injected, in the AlGaN EBL structure with high Al composition, a large amount of electrons would still spill over into the P -type layer, causing undesired effects such as efficiency droop effect, aging and light failure.

### SUMMARY

To solve the above problems, various embodiments of the present disclosure provide a nitride light emitting diode, in which, an AlGaN electron tunneling layer is inserted into at least one well layer closing to the n-type nitride layer to generate high barrier potential difference between the well layer and the AlGaN inserting layer. Therefore, electrons are difficult to transit among inserting layers of the well layer through thermionic emission, but mainly transit through tunneling, which confines electron mobility and adjusts electron distribution. Hence, electrons have less chance to spill over into the P-type nitride layer, thus improving light emitting efficiency and mitigating efficiency droop.

Some embodiments disclosed herein provide a nitride light emitting diode, comprising: an n-type nitride layer, a light emitting layer and a p-type nitride layer in sequence, wherein, the light emitting layer is a MQW structure composed of a barrier layer and a well layer, in which, an AlGaN electron tunneling layer is inserted into at least one well layer closing to the n-type nitride layer with barrier height greater than that of the barrier layer; in addition, the barriers of the well layer and the AlGaN electron tunneling layer are high enough so that electrons are difficult to transit towards thermionic emission direction, but mainly transit through tunneling in the InGaN well layers, which confines electron mobility and adjusts electron distribution, thus reducing the chance for electrons to spill over into the P-type nitride layer.

Preferably, the barrier layer is a GaN layer, and the well layer is an InGaN layer.

Preferably, an AlGaN electron tunneling layer is inserted into the middle of the well layers in the first M-pair quantum wells closing to the n-type nitride layer of the light emitting layer, where 20>M≧1.

Preferably, a single or a multiple of AlGaN electron tunneling layer(s) is inserted into the well layers in the first M-pair quantum wells closing to the n-type nitride layer of the light emitting layer.

Preferably, period of the electron tunneling layers is 2 pairs.

Preferably, range of Al-composition x in the AlGaN electron tunneling layer is: 1>x≧0.3.

Preferably, the AlGaN electron tunneling layer is 1 Å-50 Å thick.

Preferably, the AlGaN electron tunneling layer is Si doping, with high doping concentration of 1.0×10¹⁹-2.0×10²⁰ to reduce resistance. In some embodiments, the Si doping can be uniform doping, or non-uniform doping, such as delta doping.

Preferably, the nitride light emitting diode also comprises a p-type AlₓIn_{y}Ga_{1-x-y}N electron blocking layer, where 0.2>x>0. In high Al-composition AlGaN material, Mg doping is difficult with low activation efficiency, and Si doping is easier. Therefore, an AlGaN electron tunneling layer is used to lower electron concentration and mobility at front-end of the MQW. As a result, an electron blocking layer with lower Al-compositions than that of conventional LED can be applied in the p-type layer to increase Mg doping concentration and ionization efficiency of the p-type AlₓIn_{y}Ga_{1-x-y}N layer, and improve hole injection efficiency and light emitting efficiency. In some embodiments, Mg doping concentration of the p-type AlₓIn_{y}Ga_{1-x-y}N electron blocking layer is 5×10¹⁸-5×10²⁰, and preferably 5×10¹⁹.

In the light emitting region according to some embodiments, an AlGaN electron tunneling layer is inserted into the well layers at front end (the end closing to the n-type nitride layer) of the MQW. Due to high Al-composition x (preferably, x>0.3) and high barrier potential difference between the well layer and the AlGaN layer, electrons are difficult to transit over the barrier through thermionic emission, but mainly through tunneling. This AlGaN electron tunneling layer acts as a speed bump to lower the electron mobility under high current conditions, and electrons have less chance to spill over into the P-type nitride layer, thus improving hole injection efficiency and electron-hole efficiency. As a result, light emitting efficiency is improved, and efficiency droop is mitigated.

Further, as height difference between the AlGaN barrier and the well layer is high, electrons are difficult to transit over the AlGaN barrier through thermionic emission. Except those transited through electron tunneling, other electrons are confined in the well layer and forced to horizontal migration. This improves electron horizontal expansion and current uniformity in the plain, and relieves the problem of high current concentration at electrode position and low current concentration at chip edges, thereby increasing uniformity of current and luminance in the LED plain and improving antistatic capacity and resistance to ESD breakdown.

In another aspect, a light-emitting system is provided including a plurality of the LEDs described above. The light-emitting system can be used, for example, for lighting, display, signage, etc.

Other features and advantages of various embodiments of the present disclosure will be described in detail in the following specification, and it is believed that such features and advantages will become apparent in the specification or through implementations of this disclosure. The purposes and other advantages of the present disclosure can be realized and obtained in the structures specifically described in the specifications, claims and drawings.

### BRIEF DESCRIPTION OF THE DRAWINGS

The accompanying drawings, which are included to provide a further understanding of some embodiments of the present disclosure and constitute a part of this specification, together with the embodiments, are therefore to be considered in all respects as illustrative and not restrictive. In addition, the drawings are merely illustrative, which are not drawn to scale.

FIG. 1 is a gap distribution diagram of MQW and EBL in a conventional nitride light emitting diode with a high-Al-composition AlGaN EBL.

FIG. 2 is a side sectional view of a nitride light emitting diode according to some embodiments.

FIG. 3 is partial enlarged view of the light emitting area of nitride light emitting diode as shown in FIG. 2.

FIG. 4 is a gap distribution diagram of MQW and EBL of a nitride light emitting diode according to some embodiments.

FIG. 5 displays the method of electrons moving through the quantum well of a nitride light emitting diode according to some embodiments.

FIG. 6 is a gap distribution diagram of local quantum well of another nitride light emitting diode according to some embodiments.

FIG. 7 is a comparison diagram of light emitting output power between a nitride light emitting diode according to some embodiments (Sample I) and a conventional LED (Sample II) as shown in FIG. 1.

FIG. 8 is a comparison diagram of external quantum efficiency between a nitride light emitting diode according to some embodiments (Sample I) and a conventional LED (Sample II) as shown in FIG. 1.

In the drawings:

101: substrate; 102: buffer layer; 103: n-type nitride layer; 104a: first m-pair quantum wells; 104b: last n-pair quantum wells; 105: p-type electron blocking layer; 106: p-type GaN layer; 107: p-type contact layer; 104a-1: GaN barrier layer; 104a-2: InGaN well layer; 104a-3: AlGaN electron tunneling layer; 104a-4: InGaN well layer; 104a-5: AlGaN electron tunneling layer, 104a-6: InGaN well layer; 104a-7: GaN barrier layer.

### DETAILED DESCRIPTION

The present disclosure will be described in detail with reference to the embodiments and accompany drawings.

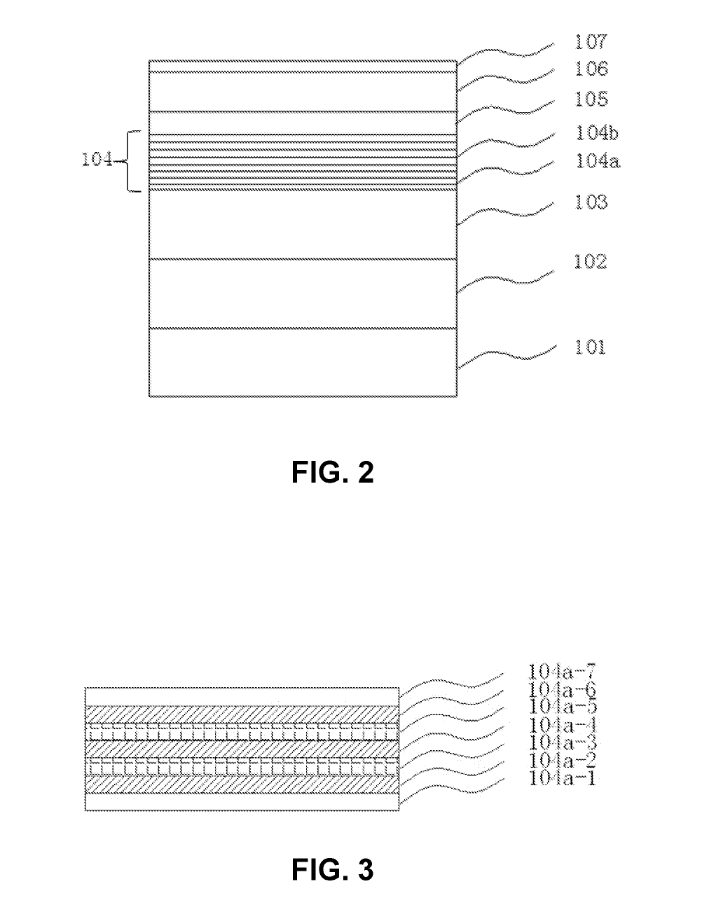

FIG. 2 discloses a nitride light emitting diode according to some embodiments, comprising: a substrate 101, a buffer layer 102, an n-type nitride layer 103, a light emitting layer 104, a p-type electron blocking layer 105, a p-type GaN layer 106 and a p-type contact layer 107, wherein, the substrate 101 is preferably a sapphire substrate, or may be GaN substrate, Si substrate or other substrates; the buffer layer 102 is made of III-based nitride material, which is preferably GaN, or may be AlN or AlGaN; the n-type nitride layer 103 is preferably made of GaN, or may be made of AlGaN material, with preferred Si doping concentration of 1×10¹⁹ cm⁻³; the light emitting layer 104 is a MQW structure, preferably composed of 5-50 pairs of quantum wells; the p-type electron blocking layer 105 is closely adjacent to the light emitting layer 104, for suppressing electrons from entering the p-type layer to combine with holes, which is preferably a p-type AlₓIn_{y}Ga_{1-x-y}N (0<x<1, 0≦y<1, x+y<1) layer; the p-type GaN layer 106 is Mg doping, with doping concentration of 1×10¹⁹-5×10²¹ cm⁻³, and preferred thickness is 100 nm-800 nm; and the p-type contact layer 107 is preferably 5 nm-20 nm thick.

The light emitting layer 104 will be described in details with reference to FIGS. 3-6. Specifically, the light emitting layer 104 is an InGaN/GaN MQW structure, wherein, the number of quantum well pairs is preferred to be at least 14. In this embodiment, the MQW structure is divided into first m-pair quantum wells 104a and last n-pair quantum wells 104b, in which, the first m-pair quantum wells 104a are adjacent to the n-type nitride layer 103, with an AlGaN electron tunneling layer inserted in the well layer, while the last n-pair quantum wells 104b are adjacent to the p-type electron blocking layer 105, where, preferred range of M and N: 1≦M<20, 8≦N≦50. In a preferred embodiment, M is 4, and N is 10.

FIG. 3 displays the inserted structure of first M-pair quantum wells, comprising a GaN barrier layer 104a-1, an InGaN well layer 104a-2, an AlGaN electron tunneling layer 104a-3, an InGaN well layer 104a-4, an AlGaN electron tunneling layer 104a-5, an InGaN well layer 104a-6 and a GaN barrier layer 104a-7, wherein, the AlGaN electron tunneling layers 104a-3 and 104a-5 have high barrier (larger than that of the GaN barrier layer 104a-1), thus requiring high Al-composition, with preferred Al-composition x range of: 1>x≧0.3. In a preferred embodiment, x is 0.3; to ensure quantum well lattice, preferably, the AlGaN electron tunneling layer is a thin structure with preferred thickness of 1 Å-50 Å, and preferably 10 Å; in some preferred embodiments, the AlGaN electron tunneling layers 104a-3 and 104a-5 are Si doping with doping concentration of 1.0×10¹⁹-2.0×10²⁰, which can be uniform doping, or non-uniform doping (such as delta doping). This high Si doping concentration can reduce resistance. Taking uniform doping as an example, the Si doping concentration is preferably 1.5×10¹⁹.

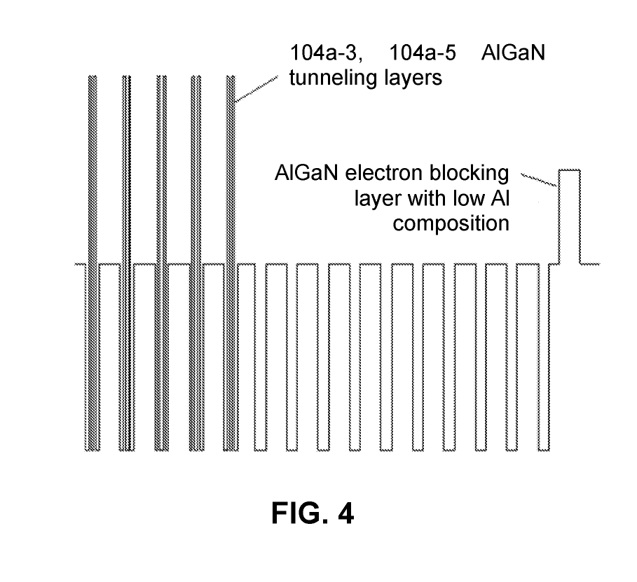

FIG. 4 displays a gap distribution diagram of MQW and EBL of a nitride light emitting diode according to some embodiments. As shown, an AlGaN electron tunneling layer with high gap is inserted into the first m-pair quantum wells so that electrons have to transit over the AlGaN barrier height or tunneling for downward transition. Due to high barrier height of the InGaN well and the AlGaN electron tunneling layer, chance for electrons to transmit (climb) over the barrier through thermionic emission can be controlled by controlling Al composition and changing barrier height, while tunneling chance can be controlled by adjusting thickness of the AlGaN inserting layer. As a result, distribution of electron wave function can be controlled effectively and accurately to maximize combination chance of electron and hole wave functions in the light emitting MQW area and to effectively improve light emitting efficiency and luminance.

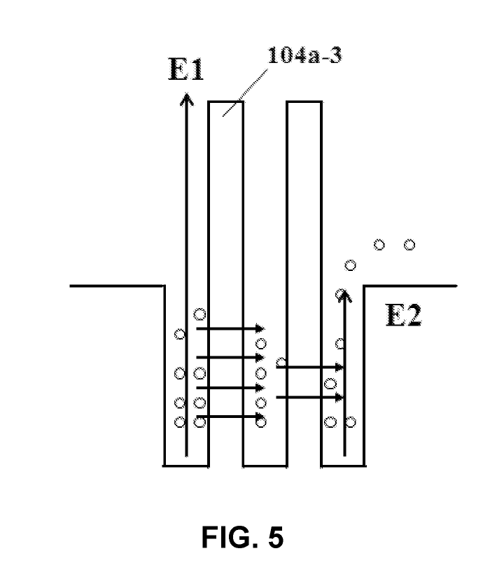

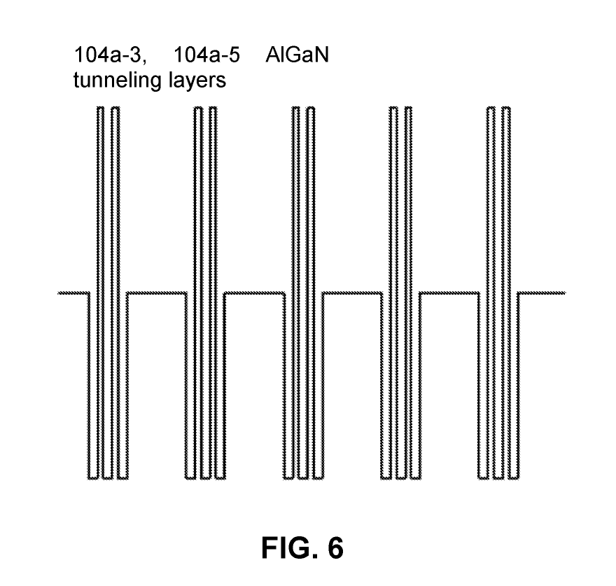

FIG. 5 displays the method of electrons moving through the quantum well of a nitride light emitting diode according to some embodiments. For example, AlGaN electron tunneling layers 104a-3 and 104a-5 with high barrier E1 are inserted into the well layer so that electrons can hardly transit over E1 but be forced to tunneling. Finally, electrons transit to the next quantum well across the barrier E2 by thermionic emission. This reduces electron migration and improves distribution uniform in the MQW.

By inserting an AlGaN layer at front-end well layers of the MQW, electron mobility and distribution in the light-emitting quantum well area are controlled. After MQW, even AlGaN electron blocking layer with low Al-composition can achieve the same electron blocking effect. Therefore, in some preferred embodiments, p-type AlGaN with low Al-composition acts as the electron blocking layer 105, wherein, preferred value range of Al-composition x is: 0.2>x>0 (preferably 0.1). The AlGaN with Al-composition can increase Mg doping concentration and ionization efficiency in the electron blocking layer, thereby increasing hole concentration and decreasing resistance in the electron blocking layer. In some preferred embodiments, Mg doping concentration of the p-type AlGaN electron blocking layer 105 is 5×10¹⁸-5×10²⁰, preferably 5×10¹⁹.

A single or a multiple of AlGaN electron tunneling layer(s) can be inserted in the well layer of first m-pair quantum wells 104a in the light emitting layer. In the embodiment as shown in FIG. 6, a dual-layer AlGaN electron tunneling layer is inserted into the well layer.

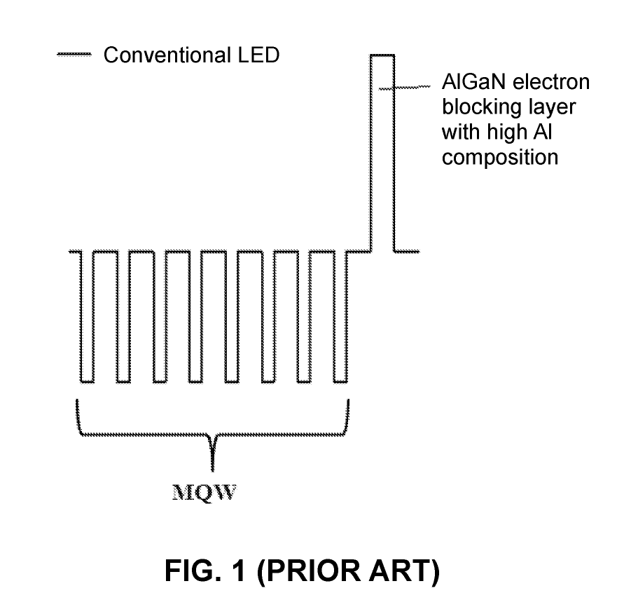

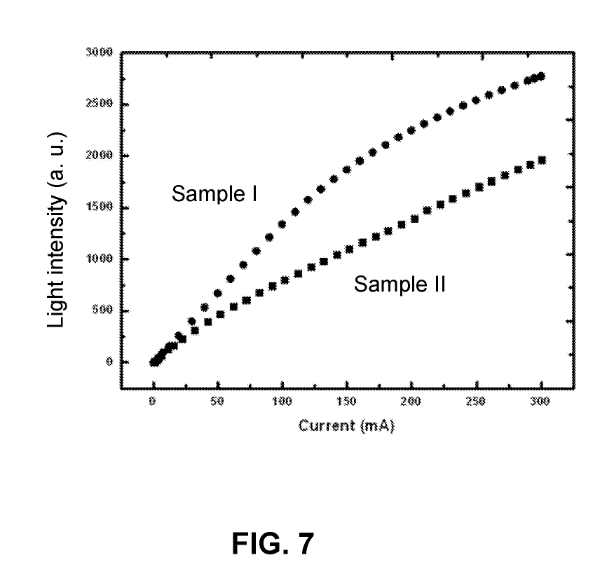

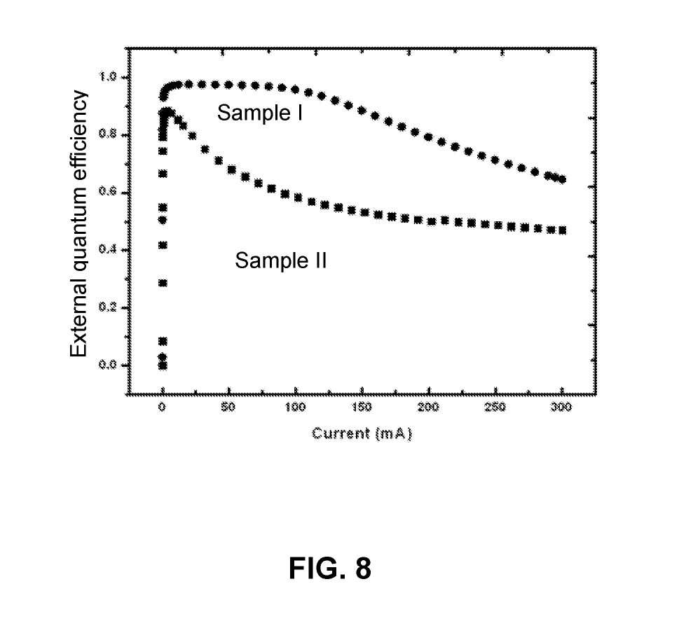

Two samples are manufactured and are described below. Sample I is a nitride light emitting diode according to some embodiments disclosed herein, and sample II is a conventional nitride light emitting diode as shown in FIG. 1. Light emitting output power and external quantum efficiency of these two samples are tested respectively. Specifically, sample I and sample II have the same substrate, buffer layer, n-type nitride layer, p-type GaN layer and p-type contact layer (selected based on aforesaid description for each layer). The light emitting layer of sample I has 14 pairs of InGaN/GaN quantum well structures, wherein, in the first 4 pairs of well layers, a 10 Å Si-doped AlGaN layer (with Al-composition of 0.3, and Si doping concentration of 1.5×10¹⁹) is inserted, and the p-type electron blocking layer is a p-type AlGaN layer with low Al-composition (Al-composition of 0.1); the light emitting layer of sample II has 14 pairs of InGaN/GaN quantum well structures, wherein, each pair of quantum wells have same structure, and the p-type electron blocking layer is a p-type AlGaN layer with high Al-composition (Al-composition of 0.4). FIG. 7 is the relationship diagram of light emitting output power and forward current of two samples. FIG. 8 displays external quantum efficiency of two samples under different current for demonstrating efficiency droop level.

FIG. 7 shows electro light-emitting intensity under different current conditions. The electro light-emitting intensity of sample I is significantly higher than that of the conventional LED. In particular, when current is 3,000 mA high, the light emitting intensity of sample I is about 50% higher than that of conventional LED.

As shown in FIG. 8, under different current conditions, sample I has significant improvement in efficiency droop compared with conventional LED. The attenuation of external quantum efficiency with current is about 20-40% lower than that of conventional LED. These results further demonstrate that the present invention can effectively improve efficiency droop and reduce non-radiative combination, thus contributing to application of LED under high current conditions.

All references referred to in the present disclosure are incorporated by reference in their entirety. Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A nitride light emitting diode, comprising:
an n-type nitride layer;
a light emitting layer; and
a p-type nitride layer;
wherein:
the light emitting layer comprises a multiple quantum well (MQW) structure including a barrier layer and a well layer;
an AlGaN electron tunneling layer is inserted into at least one well layer adjacent to the n-type nitride layer with a barrier height greater than a height of the barrier layer;
a potential barrier height difference between the well layer and the AlGaN electron tunneling layer is sufficiently high such that electrons are difficult to transit through thermionic emission, but mainly transit through tunneling.

2. The nitride light emitting diode according to claim 1, wherein: the AlGaN electron tunneling layer is inserted into a middle of first M-pair quantum wells adjacent to the n-type nitride layer, where 20>M≧1.

3. The nitride light emitting diode according to claim 1, wherein: a single AlGaN electron tunneling layer or a plurality of AlGaN electron tunneling layers are inserted into the well layers in the first M-pair quantum wells.

4. The nitride light emitting diode according to claim 1, wherein the well layer in the MQW structure is an InGaN layer.

5. The nitride light emitting diode according to claim 1, wherein Al-composition x in the AlGaN electron tunneling layer is: 1>x≧0.3.

6. The nitride light emitting diode according to claim 1, wherein the AlGaN electron tunneling layer has a thickness of 1 Å-50 Å.

7. The nitride light emitting diode according to claim 1, wherein the AlGaN electron tunneling layer is Si doped.

8. The nitride light emitting diode according to claim 7, wherein a Si doping concentration of the AlGaN electron tunneling layer is 1.0×10¹⁹-2.0×10²⁰ cm⁻³.

9. The nitride light emitting diode according to claim 7, wherein the Si doping of the AlGaN electron tunneling layer is delta doping.

10. The nitride light emitting diode according to claim 1, further comprising a p-type AlₓIn_{y}Ga_{1-x-y}N electron blocking layer, where 0.2>x>0.

11. The nitride light emitting diode according to claim 10, wherein a Mg doping concentration of the p-type AlₓIn_{y}Ga_{1-x-y}N electron blocking layer is 5×10¹⁸-5×10²⁰ cm⁻³.

12. A light-emitting system comprising a plurality of nitride light emitting diodes (LEDs), each LED comprising:
an n-type nitride layer;
a light emitting layer; and
a p-type nitride layer;
wherein:
the light emitting layer comprises a multiple quantum well (MQW) structure including a barrier layer and a well layer;
an AlGaN electron tunneling layer is inserted into at least one well layer adjacent to the n-type nitride layer with a barrier height greater than a height of the barrier layer;
a potential barrier height difference between the well layer and the AlGaN electron tunneling layer is sufficiently high such that electrons are difficult to transit through thermionic emission, but mainly transit through tunneling.

13. The system of claim 12, wherein: the AlGaN electron tunneling layer is inserted into a middle of first M-pair quantum wells adjacent to the n-type nitride layer, where 20>M≧1.

14. The system of claim 12, wherein: a single AlGaN electron tunneling layer or a plurality of AlGaN electron tunneling layers are inserted into the well layers in the first M-pair quantum wells.

15. The system of claim 12, wherein the well layer in the MQW structure is an InGaN layer.

16. The system of claim 12, wherein Al-composition x in the AlGaN electron tunneling layer is: 1>x≧0.3.

17. The system of claim 12, wherein the AlGaN electron tunneling layer has a thickness of 1 Å-50 Å.

18. The system of claim 12, wherein the AlGaN electron tunneling layer is Si doped.

19. The system of claim 18, wherein a Si doping concentration of the AlGaN electron tunneling layer is 1.0×10¹⁹-2.0×10²⁰ cm⁻³.

20. The system of claim 19, wherein the Si doping of the AlGaN electron tunneling layer is delta doping, each LED further comprising a p-type AlₓIn_{y}Ga_{1-x-y}N electron blocking layer, where 0.2>x>0, wherein a Mg doping concentration of the p-type AlₓIn_{y}Ga_{1-x-y}N electron blocking layer is 5×10¹⁸-5×10²⁰ cm⁻³.
